(19) United States
(12) Patent Application Publication
(10) Pub. No.: US 2025/0140955 A1
(43) Pub. Date: May 1, 2025

(54) BATTERY MODULE

(71) Applicant: Samsung SDI Co., Ltd., Yongin-si (KR)

(72) Inventors: Kyunghoon Park, Yongin-si (KR); Hyeongkyu Jeong, Yongin-si (KR)

(21) Appl. No.: 18/803,236

(22) Filed: Aug. 13, 2024

(30) Foreign Application Priority Data
Oct. 26, 2023 (KR) 10-2023-0145086

(51) Int. Cl. H01M 10/48; G01R 31/3835; G01R 31/396; H01H 69/02; H01M 50/583

(52) U.S. Cl. CPC H01M 10/482; G01R 31/3835; G01R 31/396; H01M 50/583; H01H 69/022; H01M 2200/103

(57) ABSTRACT

Provided is a battery module including an electronic component, in which, by improving a structure of the electronic component, a manufacturing cost of the electronic component may be reduced, and an increase in a volume of the electronic component may be suppressed. The battery module may include a voltage measurement circuit electrically connected to battery cells to measure a voltage of the battery cells, the voltage measurement circuit including a main circuit manufactured using a first method, and a fuse electrically connected to the main circuit and manufactured using a second method that is different from the first method.

### CROSS-REFERENCE TO RELATED APPLICATIONS

The present application claims priority to and the benefit of Korean Patent Application No. 10-2023-0145086, filed on Oct. 26, 2023, in the Korean Intellectual Property Office, the entire disclosure of which is incorporated herein by reference.

### BACKGROUND

### 1. Field

One or more embodiments relate to a battery module, and to a circuit configuration for measuring a temperature of a plurality of battery cells of a battery module.

### 2. Description of the Related Art

A secondary battery is chargeable and dischargeable, unlike a primary battery that is not chargeable. Low-capacity secondary batteries are used in small portable electronic devices, such as smartphones, feature phones, laptop computers, digital cameras, and camcorders, and high-capacity secondary batteries are used as motor-driving power sources, power-storing batteries, etc., for hybrid vehicles, electric vehicles, etc. A secondary battery may include an electrode assembly including a cathode and an anode, a case accommodating the electrode assembly, an electrode terminal connected to the electrode assembly, etc.

The above-described information disclosed in the technology that serves as the background of the present disclosure is only for improving the understanding of the present disclosure, and may include information that does not constitute the related art.

A battery module includes a plurality of battery cells. The battery module is configured to measure a voltage to identify a state of charge of each of the plurality of battery cells. Examples of an electronic component that measures a voltage of each battery cell may include a wire harness, a flexible printed circuit assembly (FPCA), etc.

Conventionally, the wire harness has been used as the electronic component. However, with the increasing number of battery cells in a battery module, it has become difficult to use a structure employing a wire harness due to an excessively large volume of the structure. The FPCA is available as an alternative to the wire harness. However, due to a complicated manufacturing process of the FPCA in comparison to that of the wire harness, the manufacturing cost of the FPCA is high.

### SUMMARY

One or more embodiments include a battery module including an electronic component, in which, by improving a structure of the electronic component, a manufacturing cost of the electronic component may be reduced, and an increase in a volume of the electronic component may be suppressed.

However, aspects of the present disclosure are not limited to the above, and other aspects not mentioned may be clearly understood by those of ordinary skill in the art from the description of the present disclosure described below. Additional aspects will be set forth in part in the description which follows and, in part, will be apparent from the description, or may be learned by practice of the presented embodiments of the present disclosure.

According to one or more embodiments, a battery module includes a voltage measurement circuit electrically connected to battery cells to measure a voltage of the battery cells, the voltage measurement circuit including a main circuit manufactured using a first method, and a fuse electrically connected to the main circuit, and manufactured using a second method that is different from the first method.

The first method may include a flexible die cut (FDC) method.

The second method may include a flexible printed circuit (FPC) method.

The main circuit and the fuse may be electrically coupled to each other by thermal fusion.

The main circuit and the fuse may be electrically coupled to each other by a surface mounting technology (SMT).

The main circuit and the fuse may be electrically coupled to each other by riveting.

A thickness of the fuse may be less than a thickness of the main circuit.

According to one or more embodiments, there is provided a method of manufacturing a voltage measurement circuit to be electrically connected to battery cells of a battery module to measure a voltage of the battery cells, the method including manufacturing a main circuit using a first method, and manufacturing a fuse to be electrically connected to the main circuit using a second method that is different from the first method.

The first method may include a flexible die cut (FDC) method.

The second method may include a flexible printed circuit (FPC) method.

The method may further include electrically coupling the main circuit and the fuse to each other by thermal fusion.

The method may further include electrically coupling the main circuit and the fuse to each other by a surface mounting technology (SMT).

The method may further include electrically coupling the main circuit and the fuse to each other by riveting.

A thickness of the fuse may be less than a thickness of the main circuit.

### BRIEF DESCRIPTION OF DRAWINGS

The following drawings attached to this specification illustrate embodiments of the present disclosure, and serve to further understand aspects of the present disclosure together with the detailed description of the present disclosure described later, so the present disclosure should not be construed as being limited to the matters shown in such drawings.

The above and other aspects of certain embodiments of the present disclosure will be more apparent from the following description taken in conjunction with the accompanying drawings, in which:

FIG. 1 schematically shows a configuration of a voltage measurement circuit of a battery module according to one or more embodiments of the present disclosure;

FIG. 2 shows a state in which a fuse of the voltage measurement circuit shown in FIG. 1 is separated from a main circuit of the voltage measurement circuit;

FIG. 3 is a cross-sectional view along the line III-III shown in FIG. 1;

FIG. 4 is a cross-sectional view corresponding to FIG. 3 to show a state before the fuse and the main circuit are coupled to each other; and

FIG. 5 schematically shows a process in which a main circuit pattern is processed using a flexible die cut (FDC) method.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the aspects of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction. Further, the phrase “in a schematic cross-sectional view” means when a schematic cross-section taken by vertically cutting an object portion is viewed from the side.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

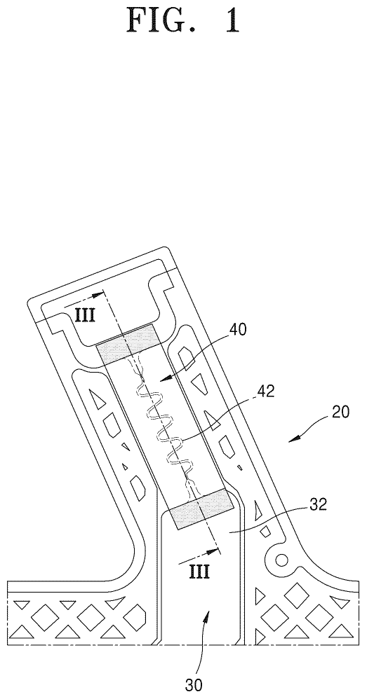

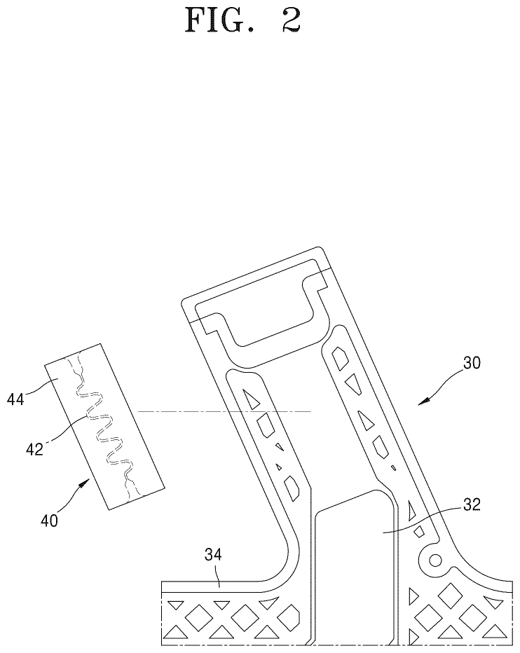

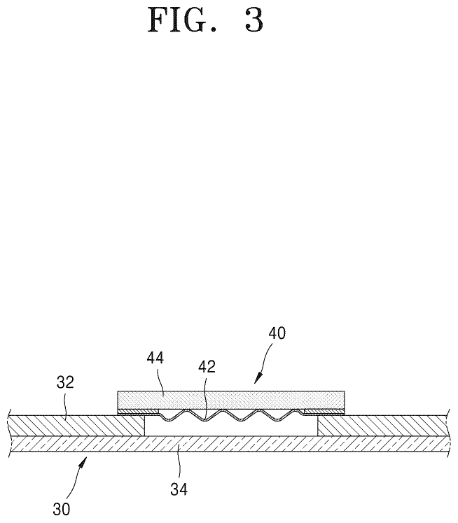

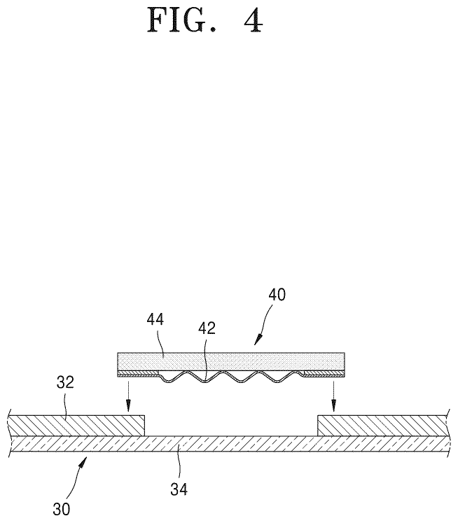

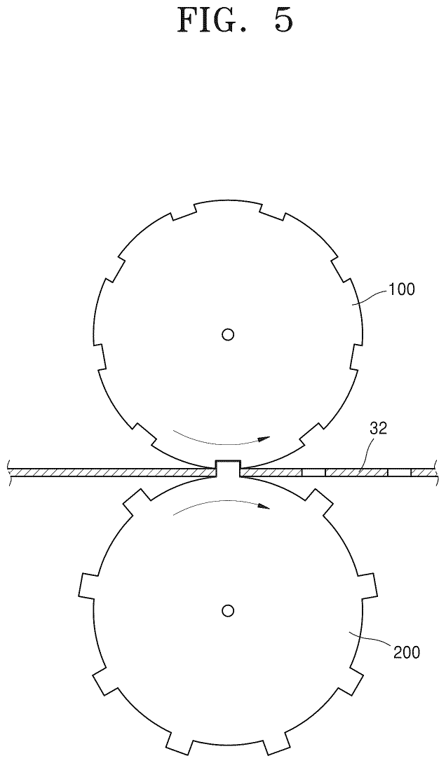

FIG. 1 schematically shows a configuration of a voltage measurement circuit of a battery module according to one or more embodiments of the present disclosure. FIG. 2 shows a state in which a fuse of the voltage measurement circuit shown in FIG. 1 is separated from a main circuit of the voltage measurement circuit. FIG. 3 is a cross-sectional view along the line III-III shown in FIG. 1. FIG. 4 is a cross-sectional view corresponding to FIG. 3 to show a state before the fuse and the main circuit are coupled to each other. FIG. 5 schematically shows a process in which a main circuit pattern is processed using a flexible die cut (FDC) method.

Referring to FIGS. 1 to 5, a battery module according to one or more embodiments of the present disclosure may include a plurality of battery cells, in one or more embodiments. The battery module may include a voltage measurement circuit 20 electrically connected to each of the plurality of battery cells. The voltage measurement circuit 20 may be installed to be coupled to, for example, a cell holder, in one or more embodiments. The voltage measurement circuit 20 may include a main circuit 30 and a fuse 40.

The main circuit 30 may constitute most of the voltage measurement circuit 20. The main circuit 30 may be manufactured using a first method. The first method may be an FDC method. According to the FDC method, a conductor part of a circuit may be manufactured by cutting a thin metal plate using a roller mold, and by attaching the cut metal plate to a flexible non-conductive resin plate. The FDC method may include only physical processes. As a result, the FDC method may not need processes, such as photo-masking, development, etching, etc., unlike a general printed circuit board manufacturing method. As a result, the FDC method may be performed at a cost that is much lower than that of a flexible printed circuit (FPC) method. A width of a fine pattern manufactured using the FDC method may be at least about 0.3 mm. If an electric circuit suitably includes a fine pattern of a width of about 0.3 mm or less, it may be difficult to use the FDC method. The main circuit 30 may have a structure in which a main circuit pattern 32 is attached to an FDC film resin 34. The main circuit pattern 32 may be formed by being physically cut using a roller mold. FIG. 5 schematically depicts a process in which the main circuit pattern 32 is formed as a metal thin plate passes between an upper roller 100 and a lower roller 200, which may respectively include uneven patterns on their surfaces.

The fuse 40 may be electrically connected to the main circuit 30. The fuse 40 may constitute a safety device for reducing or preventing propagation of fire to a nearby circuit in case of over-current and/or short-circuit in the battery module. The width of the fine pattern of the electric circuit of the fuse 40 may be about 0.08 mm or less. If the width of the fine pattern of the fuse 40 exceeds about 0.08 mm, the fuse 40 may not satisfactorily serve as a fuse. The fuse 40 may be manufactured using a method that is different from the first method. The fuse 40 may be manufactured using a second method that is different from the first method. For example, the fuse 40 may be manufactured using the FPC method. As a chemical process is applied to the FPC method, the width of the fine pattern being about 0.08 mm or less may be implemented. The fuse 40 is more expensive than the main circuit 30 in terms of a manufacturing cost. The fuse 40 may be separately provided as a reel-based coupon. A reel-based coupon may mean that multiple fuses can be manufactured to be wound in a roll structure. The fuse coupon, which may have a roll structure, can be used by unwinding and cutting it. The fuse 40 may be configured with a fuse pattern 42 being formed on an FPC film resin 44. The fuse pattern 42 may be formed by chemical processes, such as masking, development, etching, etc., like a general FPC manufacturing method.

The main circuit 30 and the fuse 40 may be electrically coupled to each other by thermal fusion. The main circuit 30 and the fuse 40 may be electrically coupled to each other using a surface mounting technology (SMT). An example of a SMT may be coupling based on soldering. The main circuit 30 and the fuse 40 may be electrically coupled to each other using riveting. The main circuit 30 and the fuse 40 may be electrically coupled to each other using various methods. The fuse 40 may be coupled to the main circuit 30 in the form of a patch.

A thickness of the fuse 40 may be less than that of the main circuit 30. The fuse 40 may be manufactured using the second method (e.g., the FPC method), such that a fine line width of a circuit of the fuse 40, as well as a thickness of the fuse 40, may be respectively less than those of the main circuit 30.

By coupling the main circuit 30 and the fuse 40 of the voltage measurement circuit 20 to each other using different manufacturing methods for them, the voltage measurement circuit 20 may have a hybrid structure. The voltage measurement circuit 20 having the hybrid structure may employ the FPC method providing a high manufacturing cost only for a suitable part, and may apply the FDC method providing a low manufacturing cost and a simple structure, thereby significantly suppressing an increase in a volume of an electronic component if compared to a conventional configuration of an electronic component based on a wire harness. In comparison to a comparative example of a voltage measurement circuit to which the FPC method is applied, the voltage measurement circuit 20 having the hybrid structure may innovatively reduce a manufacturing cost thereof, and may implement a safety function of satisfactorily reducing or preventing fire propagation.

While the present disclosure is described by some embodiments and drawings, the present disclosure is not limited thereby, and various modifications and changes may be made by those of ordinary skill in the art within the technical spirit of the present disclosure and the equivalent range to the claims set forth below.

According to the present disclosure, among electronic components for measuring a voltage of a battery cell of the battery module, the main circuit may be manufactured using the first method providing a low manufacturing cost, and the fuse may be manufactured using the second method providing a higher manufacturing cost than the first method, while significantly reducing the manufacturing cost of the main circuit constituting most of the voltage measurement circuit as compared to the main circuit manufactured using the FPCA method, while reducing the manufacturing cost of the electronic component of the battery module, and while maintaining the significantly small volume of the electronic component in comparison to the wire harness.

However, aspects that may be obtained through the present disclosure are not limited to the above-described aspects, and other aspects not mentioned may be clearly understood by those of ordinary skill in the art from the description of the present disclosure described below.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope of the present disclosure as defined by the following claims.

1. A battery module comprising a voltage measurement circuit electrically connected to battery cells to measure a voltage of the battery cells, the voltage measurement circuit comprising:
a main circuit manufactured using a first method; and
a fuse electrically connected to the main circuit, and manufactured using a second method that is different from the first method.

2. The battery module as claimed in claim 1, wherein the first method comprises a flexible die cut (FDC) method.

3. The battery module as claimed in claim 1, wherein the second method comprises a flexible printed circuit (FPC) method.

4. The battery module as claimed in claim 1, wherein the main circuit and the fuse are electrically coupled to each other by thermal fusion.

5. The battery module as claimed in claim 1, wherein the main circuit and the fuse are electrically coupled to each other by a surface mounting technology (SMT).

6. The battery module as claimed in claim 1, wherein the main circuit and the fuse are electrically coupled to each other by riveting.

7. The battery module as claimed in claim 1, wherein a thickness of the fuse is less than a thickness of the main circuit.

8. A method of manufacturing a voltage measurement circuit to be electrically connected to battery cells of a battery module to measure a voltage of the battery cells, the method comprising:
manufacturing a main circuit using a first method; and
manufacturing a fuse to be electrically connected to the main circuit using a second method that is different from the first method.

9. The method as claimed in claim 8, wherein the first method comprises a flexible die cut (FDC) method.

10. The method as claimed in claim 8, wherein the second method comprises a flexible printed circuit (FPC) method.

11. The method as claimed in claim 8, further comprising electrically coupling the main circuit and the fuse to each other by thermal fusion.

12. The method as claimed in claim 8, further comprising electrically coupling the main circuit and the fuse to each other by a surface mounting technology (SMT).

13. The method as claimed in claim 8, further comprising electrically coupling the main circuit and the fuse to each other by riveting.

14. The method as claimed in claim 8, wherein a thickness of the fuse is less than a thickness of the main circuit.

15. The battery module as claimed in claim 1, wherein the main circuit has a structure in which a main circuit pattern is attached to an FDC film resin, and/or
wherein the fuse comprises a fuse pattern on an FPC film resin.
